(19) United States
(12) Patent Application Publication
(10) Pub. No.: US 2010/0059775 A1
(43) Pub. Date: Mar. 11, 2010

(54) Organic light emitting diode and method of fabricating the same

(75) Inventors: Mi-Kyung Kim, Yongin-City (KR); Min-Seung Chun, Yongin-City (KR); Dong-Heon Kim, Yongin-City (KR); Jung-Ha Son, Yongin-City (KR); Jae-Hyun Kwak, Yongin-City (KR)

Correspondence Address: ROBERT E. BUSHNELL & LAW FIRM, 2029 K STREET NW, SUITE 600, WASHINGTON, DC, 20006-1004, US

(73) Assignee: Samsung Mobile Display Co., Ltd., Yongin-City (KR)

(21) Appl. No.: 12/461,873

(22) Filed: Aug. 26, 2009

(30) Foreign Application Priority Data
Aug. 26, 2008 (KR) 10-2008-0083344

(51) Int. Cl. H01L 51/52; H01L 51/56

(52) U.S. Cl. 257/98; 438/29; 257/40; 257/E51.018; 257/E21.158

(57) ABSTRACT

Provided are an organic light emitting diode and a method of fabricating the same, which can reduce the efficiency of electron injection and transport at low brightness to cause low luminous efficiency, thus preventing the organic light emitting diode from emitting light when displaying black. The organic light emitting diode includes a first electrode, an emission layer disposed on the first electrode, a second electrode disposed on the emission layer, and a metal layer formed of a metal element to a thickness of 5 to less than 50 Å. The metal layer is disposed between the first electrode and the emission layer or between the emission layer and the second electrode.

### CLAIM OF PRIORITY

This application makes reference to, incorporates the same herein, and claims all benefits accruing under 35 U.S.C. §119 from an application earlier filed in the Korean Intellectual Property Office on 26 Aug. 2008 and there duly assigned Serial No. 10-2008-0083344.

### BACKGROUND OF THE INVENTION

1. Field of the Invention

The present invention relates to an organic light emitting diode and a method of fabricating the same, and more particularly, to an organic light emitting diode and a method of fabricating the same, which can reduce the efficiency of electron injection and transport at low brightness to cause low luminous efficiency, thus preventing the organic light emitting diode from emitting light when displaying black.

2. Discussion of Related Art

An organic light emitting diode is a self-emissive display which is thin and light, has a simple structure, and is easy to fabricate. Moreover, there are advantages in that it provides high picture quality and wide viewing angle, displays perfect moving pictures with high color purity, and has electrical properties suitable for mobile displays due to its low power consumption and low driving voltage.

A typical organic light emitting diode has a structure that includes a pixel electrode, an emission layer (EML) disposed on the pixel electrode, and an opposite electrode disposed on the emission layer.

Moreover, in order to efficiently inject or transport electrons from the opposite electrode to the emission layer, the organic light emitting diode may further include at least one layer including an electron transport layer (ETL) or an electron injection layer (EIL) between the opposite electrode and the emission layer.

In the conventional structure of the organic light emitting diode, the electron transport layer or the electron injection layer disposed between the opposite electrode and the emission layer includes a compound such as LiF or LiQ. However, the above structure has disadvantages in that, since it has high luminous efficiency even at low brightness (below about 1 cd/m²) for displaying black color, the organic light emitting diode emits a small amount of light even while displaying black color. In the case where the organic light emitting diode slightly emits light while displaying black as mentioned above, the contrast of the organic light emitting diode is lowered, and thus black color is not displayed properly in a dark environment, which results in poor picture quality of the organic light emitting diode.

### SUMMARY OF THE INVENTION

The present invention provides an organic light emitting diode and a method of fabricating the same, which can reduce the efficiency of electron injection and transport at low brightness to cause low luminous efficiency, thus preventing the organic light emitting diode from emitting light while displaying black color.

According to an embodiment of the present invention, an organic light emitting diode includes a first electrode; an emission layer disposed on the first electrode; a second electrode disposed on the emission layer, and a metal layer formed of a metal element to a thickness of no less than 5 Å to less than 50 Å. The metal layer is disposed between the first electrode and the emission layer or between the emission layer and the second electrode. The emission layer emits light.

According to another embodiment of the present invention, a method of fabricating an organic light emitting diode is provided. The method includes forming a first electrode on a substrate; forming an emission layer on the first electrode; forming a second electrode on the emission layer, and forming a metal layer that includes a metal element and has a thickness of no less than 5 Å to less than 50 Å. The metal layer is formed between the first electrode and the emission layer or between the emission layer and the second electrode.

According to another embodiment of the present invention, an organic light emitting diode includes a first electrode; a hole injection layer formed on the first electrode; a hole transport layer formed on the hole injection layer; an emission layer disposed on the hole transport layer, the emission layer emitting light; a metal layer disposed on the emission layer; and a second electrode disposed on the metal layer. The metal layer has a thickness no less than 5 Å and less than 50 Å.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIGS. 1A and 1B are cross-sectional views of an organic light emitting diode according to a first embodiment of the present invention.

FIG. 2 is a cross-sectional view of the organic light emitting diode coupled to a thin film transistor according to another embodiment of the present invention.

FIG. 3 is a flowchart showing the steps of manufacturing an organic light emitting diode that includes a metal layer according to another embodiment of the present invention.

### DETAILED DESCRIPTION OF EXEMPLARY EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

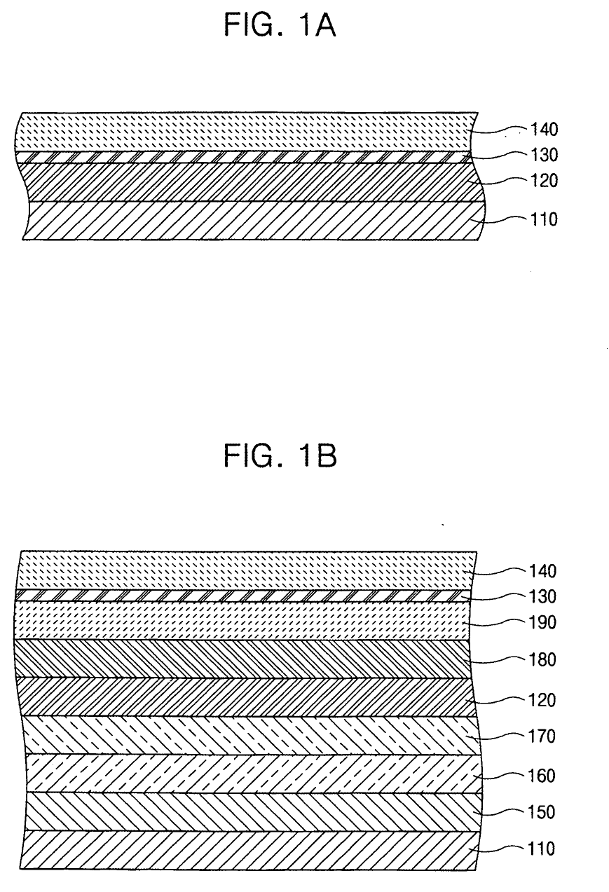

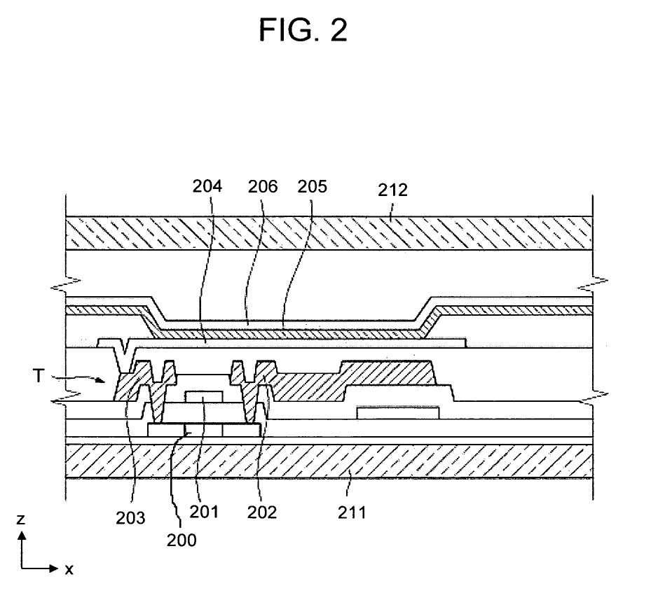

FIGS. 1A and 1B are cross-sectional views of an organic light emitting diode according to a first embodiment of the present invention. FIG. 2 is a cross-sectional view of the organic light emitting diode coupled to a thin film transistor according to another embodiment of the present invention.

First, referring to FIG. 1A, a first electrode 110 is formed on a substrate (not shown). The substrate may be made of a material such as glass, plastic or stainless steel. Referring to FIG. 2, a thin film transistor T that includes a semiconductor layer 200, a gate electrode 201, and a source electrode 202, a drain electrode 203 may be further formed on the substrate 211. The first electrode 204 is formed on the thin film transistor T, and the second electrode 206 is formed on the first electrode 204. The element 205 refers to a layer that is disposed between the first electrode 204 and the second electrode 206. In the structure shown in FIG. 1A, the element 205 may include an emission layer and a metal layer. Another substrate 212 may be disposed on the top of the organic light emitting diode. The thin film transistor T is electrically connected to the first electrode 204.

The first electrode 110 may be an anode, and may be a transparent electrode or a reflective electrode. In the case where the first electrode 110 is a transparent electrode, it may be formed of indium tin oxide (ITO), indium zinc oxide (IZO), tin oxide (TO), or zinc oxide (ZnO). Otherwise, in the case where the first electrode 110 is a reflective electrode, it may have a structure in which a reflective layer made of a material including silver (Ag), aluminum (Al), chromium (Cr), molybdenum (Mo), tungsten (W), titanium (Ti), gold (Au), palladium (Pd) or an alloy thereof is provided, and a transparent layer made of a material including ITO, IZO, TO or ZnO is stacked on the reflective layer. The first electrode 110 may be formed by sputtering, vapor phase deposition, ion beam deposition, electron beam deposition, or laser ablation.

Subsequently, an emission layer 120 is formed on the first electrode 110. The material of the emission layer 120 is not limited to any particular one and the emission layer 120 may be formed of a material selected from host materials and dopant materials, which are well known in the art.

The host materials may include distyrylarylene (DSA), distyrylarylene derivatives, distyrylbenzene (DSB), distyrylbenzene derivatives, BAlq, tris(8-quinolinolato)aluminum (Alq₃), 4,4′-N,N′-dicarbazole-biphenyl (CBP), BCP, DCB, and the like.

The dopant materials may include fluorescent dopants and phosphorescent dopants. The fluorescent dopants may include 4,4′-bis(2,2′-diphenyl vinyl)-1,1′-biphenyl (DPVBi), distyrylamine derivatives, pyrene derivatives, perylene derivatives, distyrylbiphenyl (DSBP) derivatives, 10-(1,3-benzothiazol-2-yl)-1,1,7,7-tetramethyl-2,3,6,7-tetrahydro-1H,5H,11H-pyrano(2,3-f)pyrido(3,2,1-ij)quinolin-11-one (C545T), quinacridone derivatives, 4-(dicyanomethylene)-2-tert-butyl-6-(1,1,7,7-tetramethyljulolidyl-9-enyl)-4H-pyran (DCJTB), 4-(dicyanomethylene)-2-methyl-6-(p-dimethylaminostyryl)-4H-pyran (DCM), and the like.

Meanwhile, the phosphorescent dopants may include bis(3,5-difluoro-2-(2-pyridyl)phenyl-(2-carboxypyridyl)iridium (F₂Irpic), (F₂ppy)₂Ir(tmd), tris(2-phenylpyridine)iridium(III) (Ir(PPy)₃), PQIr, Btp₂Ir(acac), 2,3,7,8,12,13,17,18-octaethyl-21H,23H-porphyrin-platinium(II) (PtOEP), Ir(piq)₂(acac), and the like.

Next, a metal layer 130, which is made of a single metal element, is formed on the emission layer 120. Preferably, the single metal element is selected from the group consisting of magnesium (Mg), calcium (Ca), and barium (Ba). Moreover, the metal layer 130 is formed to have a thickness of 5 to less than 50 Å. If the thickness is less than 5 Å, it is difficult for the metal layer 130 to properly perform the functions of injecting and transporting electrons to the emission layer 120 at high brightness, which is not to display black. Otherwise, if the thickness is more than or equal to 50 Å, the metal layer 130 has high electron injection efficiency, and thus it is difficult to prevent injection and transport of electrons to the emission layer 120 at a low brightness of about 1 cd/m², for example, for displaying black.

Accordingly, when the metal layer 130 is formed to a thickness of 5 to less than 50 Å, it is possible to significantly reduce the luminous efficiency of the emission layer 120 by reducing the efficiency of electron injection and transport to the emission layer 120 at low brightness for displaying black. Moreover, the metal layer 130 can secure the same luminous efficiency as the conventional one since it performs the functions of injecting and transporting electrons to the same degree as the conventional one at high brightness, which is not to display black.

The metal layer 130 may be an electron injection layer.

In the organic light emitting diode, the emission layer 120 is formed of a phosphorescent material, which can use triplet excitions having a generation probability of 75%, and thereby the luminous efficiency, power consumption, and color reproduction are improved. In the case where the emission layer 120 is formed of a phosphorescent material, light emission is made even at low brightness for displaying black due to high luminous efficiency, and thus it is most likely that black color mixed with red, green, or blue color is displayed. Therefore, in the case where the emission layer 120 is formed of a phosphorescent material, it is necessary to provide the metal layer 130 that can reduce the efficiency of electron injection and transport to the emission layer 120 at a low brightness of about 1 cd/m² for displaying black.

Then, a second electrode 140 is formed on the metal layer 130. The second electrode 140 may be a cathode electrode, and may be a transparent electrode or a reflective electrode. In the case where the second electrode 140 is a transparent electrode, it may be formed of a material selected from the group consisting of Mg, Ca, Al, Ag, and an alloy thereof, which are conductive metals having a low work function, to have a small thickness such that light can transmit. Otherwise, in the case where the second electrode 140 is a reflective electrode, it may be formed to have such a large thickness that it reflects light. In the case where the second electrode 140 is formed of an alloy containing metal elements, the metal layer 130 may be formed of a single metal element selected from the group consisting of the metal elements contained in the alloy.

Moreover, as shown in FIG. 1B, the organic light emitting diode according to the first embodiment of the present invention may further include at least one of a hole injection layer 150, a hole transport layer 160, and an electron blocking layer 170, which are interposed between the first electrode 110 and the emission layer 120 to efficiently inject and transport electrons or holes from the first electrode 110 to the emission layer 120.

The hole injection layer 150 may be formed of an arylamine compound or a starburst type amine. In more detail, the hole injection layer 150 may be formed of 4,4,4-tris(3-methylphenyl(phenyl)amino)triphenylamine (m-MTDATA), 1,3,5 -tris [4-(3-methylphenyl(phenyl)amino)phenyl]benzene (m-MTDATB), or copper phthalocyanine (CuPc).

The hole transport layer 160 may be formed of an arylene diamine derivative, a starburst type compound, a biphenyldiamine derivative having a spiro group, or a ladder type compound. In more detail, the hole transport layer 160 may be formed of N,N′-diphenyl-N,N′-bis(3-methylphenyl)-1,1′-biphenyl-4,4′-diamine (TPD), N,N′-di(naphthalene-1-yl)-N,N′-diphenyl-benzidine (α-NPD), or N,N′-diphenyl-N,N′-bis(1-naphthyl)-(1,1′-biphenyl)-4,4′-diamine (NPB).

The electron blocking layer 170 serves to prevent diffusion of excitons generated in the emission layer 120 during driving of the organic light emitting diode and may be formed of BAlq, BCP, CF-X, TAZ, or spiro-TAZ.

Moreover, as shown in FIG. 1B, the organic light emitting diode according to the first embodiment of the present invention may further include at least one of a hole blocking layer 180 and an electron transport layer 190, which are disposed between the emission layer 120 and the metal layer 130 to efficiently inject and transport electrons or holes from the second electrode 140 to the emission layer 120.

The hole blocking layer 180 may be formed of 2-(4-biphenyl)-5-(4-tert-butylphenyl)-1,3,4-oxydiazole (PBD), spiro-PBD, or 3-(4-t-butylphenyl)-4-phenyl-5-(4-biphenyl)-1,2,4-triazole (TAZ).

The electron transport layer 190 may be formed of TAZ, PBD, Spiro-PBD, Alg₃, BAlq, or SAlq.

Meanwhile, an organic light emitting diode according to a second embodiment of the present invention has a structure in which a first electrode is a cathode and a second electrode is an anode, which is an opposite arrangement of the first embodiment. In this case, the organic light emitting diode according to the second embodiment of the present invention may have a structure, in which a first electrode, a metal layer, an emission layer, a second electrode are sequentially stacked. Moreover, the organic light emitting diode according to the second embodiment of the present invention may further include at least one of a hole blocking layer and an electron transport layer between the metal layer and the emission layer. Furthermore, the organic light emitting diode according to the second embodiment of the present invention may further include at least one of a hole injection layer, a hole transport layer, and an electron blocking layer between the emission layer and the second electrode. Description for the respective layers is the same as the first embodiment.

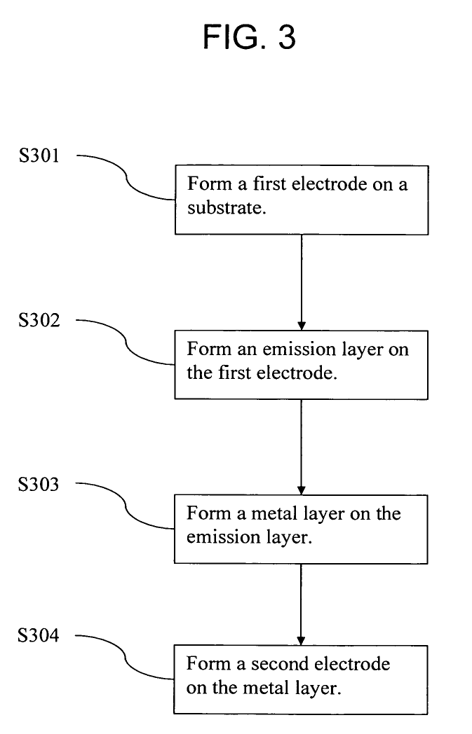

FIG. 3 is a flowchart showing the steps of manufacturing an organic light emitting diode that includes a metal layer according to another embodiment of the present invention. Referring to FIG. 1A and 3, a first electrode 110 is formed on a substrate (S301). An emission layer 120 is formed on the first electrode 110 (S302). A metal layer 130 is formed on the emission layer 120 (S303). The metal layer 130 may include a metal element and has a thickness of no less than 5 Å and less than 50 Å. A second electrode 140 is formed on the metal layer 130 (S304). The flowchart of FIG. 3 shows the metal layer 130 is formed on the emission layer 120. The metal layer 130, however, can be formed before forming the emission layer 120. In this case, the metal layer 130 is disposed between the metal layer 120 and the first electrode 110.

The following examples are provided for a better understanding of the present invention; however, the present invention is not limited thereto.

### EXPERIMENTAL EXAMPLE 1

A first electrode was formed of indium tin oxide (ITO) to a thickness of 130 nm. Subsequently, a hole injection layer, which was made of IDE-406 (manufactured by Idemitsu) as tertiary amine compound to a thickness of 210 nm, was formed on the first electrode, and a hole transport layer, which was made of NPB to a thickness of 20 nm, was formed on the hole injection layer. A red phosphorescent emission layer having a thickness of 40 nm was formed on the hole transport layer using a mixture of CBP as a host and Ir(piq)₃ as a dopant at a concentration of 15 wt %. An electron transport layer, which was made of Alq₃ to a thickness of 30 nm, was formed on the red phosphorescent emission layer. Subsequently, a metal layer, which was made of Mg as a single metal element to a thickness of 10 Å, was formed on the electron transport layer. A second electrode, which was formed of an MgAg layer to a thickness of 200 Å, was formed on the metal layer.

### EXPERIMENTAL EXAMPLE 2

An organic light emitting diode was prepared in the same manner as in Experimental Example 1, except that a metal layer was made of Mg as a single metal element to a thickness of 30 Å.

### COMPARATIVE EXAMPLE 1

An organic light emitting diode was prepared in the same manner as in Experimental Example 1, except that an electron injection layer, which was formed of a LiQ layer to a thickness of 5 Å, was formed on the electron transport layer, and a second electrode, which was formed of an MgAg layer to a thickness of 200 Å, was formed on the electron injection layer.

### COMPARATIVE EXAMPLE 2

An organic light emitting diode was prepared in the same manner as in Experimental Example 1, except that a metal layer was formed of Mg as a single metal element to a thickness of 3 Å.

### COMPARATIVE EXAMPLE 3

An organic light emitting diode was prepared in the same manner as in Experimental Example 1, except that a metal layer was formed of Mg as a single metal element to a thickness of 60 Å.

Table 1 shows luminous efficiency (cd/A) at a brightness of 1 cd/m2, luminous efficiency (cd/A) at a brightness of 1300 cd/m2, and S-ratio representing a ratio of luminous efficiency (cd/A) at a brightness of 1300 cd/m² with respect to luminous efficiency (cd/A) at a brightness of 1 cd/m² in the organic light emitting diodes according to Experimental Examples 1 and 2 and Comparative Examples 1 to 3.

TABLE 1

| | Luminous Efficiency | Luminous Efficiency | |
|---|---|---|---|
| | (cd/A) at 1 cd/m² | (cd/A) at 1300 cd/m² | S-Ratio |
| Experimental | 22.2 | 27.5 | 1.24 |
| Example 1 | | | |
| Experimental | 23.2 | 27.1 | 1.17 |
| Example 2 | | | |
| Comparative | 23.3 | 25.4 | 1.09 |
| Example 1 | | | |
| Comparative | 31.9 | 32.5 | 1.02 |
| Example 2 | | | |
| Comparative | 32.8 | 33.5 | 1.02 |
| Example 3 | | | |

It can be seen from Table 1 that the values of S-ratio in the case of the organic light emitting diodes according to Experimental Examples 1 and 2 are higher than that in the case of the organic light emitting diode according to Comparative Example 1 having the LiQ layer. The S-ratio is a value representing a ratio of luminous efficiency (cd/A) at a brightness of 1300 cd/m² with respect to luminous efficiency (cd/A) at a brightness of 1 cd/m². The higher the value of S-ratio is, the lower the luminous efficiency at low brightness is and the higher the luminous efficiency at high brightness is. Thus higher S-ratio is desirable to display perfect black color. Accordingly, it can be seen that, in the case of the organic light emitting diodes according to Experimental Examples 1 and 2 in which the metal layer was formed of Mg, instead of the LiQ layer, to a thickness of 5 to 50 Å, light of other colors is not emitted when displaying black, and thus it is possible to improve the contrast of the organic light emitting diode.

Moreover, comparing the organic light emitting diodes according to Comparative Examples 2 and 3 with that according to Comparative Example 1, it can be seen that there is little difference in the values of S-ratio when the thickness is out of the range of 5 to less than 50 Å, even if the metal layer formed of Mg instead of the LiQ layer is used. Accordingly, it can be seen that, when the metal layer including Mg is formed to a thickness of 5 to less than 50 Å, light of other colors is not emitted when displaying black, and thus it is possible to improve the contrast of the organic light emitting diode.

As described above, according to the present invention, a metal layer formed of a single metal layer is formed to a thickness of 5 to less than 50 Å between a cathode and an emission layer, so that it is possible to reduce the efficiency of electron injection and transport at low brightness to cause low luminous efficiency, thus preventing the organic light emitting diode from emitting light when displaying black. As a result, it is possible to improve the contrast of the organic light emitting diode and achieve high picture quality.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. An organic light emitting diode comprising:
a first electrode;
an emission layer disposed on the first electrode, the emission layer emitting light;
a second electrode disposed on the emission layer; and
a metal layer formed of a metal element to a thickness of no less than 5 Å and less than 50 Å, the metal layer being disposed between the first electrode and the emission layer or between the emission layer and the second electrode.

2. The organic light emitting diode of claim 1, wherein the metal element is selected from the group consisting of magnesium (Mg), calcium (Ca), and barium (Ba).

3. The organic light emitting diode of claim 1, wherein the emission layer includes a phosphorescent material.

4. The organic light emitting diode of claim 1, wherein the first electrode is a cathode and is formed of an alloy, the metal element of the metal layer disposed between the first electrode and the emission layer including an element selected from the group consisting of metal elements that form the alloy of the first electrode.

5. The organic light emitting diode of claim 1, wherein the second electrode is a cathode and is formed of an alloy, the metal element of the metal layer disposed between the second electrode and the emission layer including an element selected from the group consisting of metal elements that form the alloy of the second electrode.

6. The organic light emitting diode of claim 1, wherein the metal layer includes an electron injection layer.

7. The organic light emitting diode of claim 1, further comprising a thin film transistor electrically connected to the first electrode, the thin film transistor including a semiconductor layer, a gate electrode and source/drain electrodes.

8. A method of fabricating an organic light emitting diode, comprising:
forming a first electrode on a substrate;
forming an emission layer on the first electrode;
forming a second electrode on the emission layer; and
forming a metal layer that includes a metal element and has a thickness of no less than 5 Å and less than 50 Å, the metal layer being formed between the first electrode and the emission layer or between the emission layer and the second electrode.

9. The method of claim 8, wherein the metal element is selected from the group consisting of magnesium (Mg), calcium (Ca), and barium (Ba).

10. The method of claim 8, wherein the first electrode is a cathode and is formed of an alloy, the metal element of the metal layer disposed between the first electrode and the emission layer including an element selected from the group consisting of metal elements that form the alloy of the first electrode.

11. The method of claim 8, wherein the second electrode is a cathode and is formed of an alloy, the metal element of the metal layer disposed between the second electrode and the emission layer including an element selected from the group consisting of metal elements that form the alloy of the second electrode.

12. The method of claim 8, wherein the metal layer includes an electron injection layer.

13. An organic light emitting diode comprising:
a first electrode;
a hole injection layer formed on the first electrode;
a hole transport layer formed on the hole injection layer;
an emission layer disposed on the hole transport layer , the emission layer emitting light;
a metal layer disposed on the emission layer, the metal layer having a thickness no less than 5 Å and less than 50 Å; and
a second electrode disposed on the metal layer.

14. The organic light emitting diode of claim 13, wherein the metal element is selected from the group consisting of magnesium (Mg), calcium (Ca), and barium (Ba).

15. The organic light emitting diode of claim 13, wherein the emission layer includes a phosphorescent material.

16. The organic light emitting diode of claim 13, wherein the first electrode is a cathode and is formed of an alloy, the metal element of the metal layer disposed between the first electrode and the emission layer including an element selected from the group consisting of metal elements that form the alloy of the first electrode.

17. The organic light emitting diode of claim 13, wherein the second electrode is a cathode and is formed of an alloy, the metal element of the metal layer disposed between the second electrode and the emission layer including an element selected from the group consisting of metal elements that form the alloy of the second electrode.

18. The organic light emitting diode of claim 13, wherein the metal layer includes an electron injection layer.

19. The organic light emitting diode of claim 13, further comprising a thin film transistor electrically connected to the first electrode, the thin film transistor including a semiconductor layer, a gate electrode and source/drain electrodes.

20. The organic light emitting diode of claim 13, further comprising:
an electron transport layer disposed between the emission layer and the metal layer; and
a hole blocking layer disposed between the emission layer and the electron transport layer.
